(19) United States
(12) Patent Application Publication
(10) Pub. No.: US 2014/0131777 A1
(43) Pub. Date: May 15, 2014

(54) INTEGRATED CIRCUITS AND METHODS FOR FABRICATING INTEGRATED CIRCUITS WITH SALICIDE CONTACTS ON NON-PLANAR SOURCE/DRAIN REGIONS

(71) Applicant: GLOBALFOUNDRIES, INC., Grand Cayman (KY)

(72) Inventors: Hoong Shing Wong, Clifton Park, NY (US); Min-hwa Chi, Malta, NY (US)

(73) Assignee: GLOBALFOUNDRIES, INC., Grand Cayman (KY)

(21) Appl. No.: 13/677,651

(22) Filed: Nov. 15, 2012

(51) Int. Cl. H01L 29/78; H01L 21/04

(52) U.S. Cl. CPC H01L 29/78; H01L 21/04
USPC 257/288; 438/478

(57) ABSTRACT

Integrated circuits and methods for fabricating integrated circuits are provided. In an embodiment, a method for fabricating an integrated circuit includes forming a fin over a semiconductor substrate. The method further includes selectively epitaxially growing a silicon-containing material on the fin and providing the fin with a diamond-shaped cross-section and with an upper portion and a lower portion. The lower portion of the fin is covered with a masking layer. Further, a salicide layer is formed on the upper portion of the fin, and the masking layer prevents formation of the salicide layer on the lower portion of the fin.

### TECHNICAL FIELD

The present disclosure generally relates to integrated circuits and methods for fabricating integrated circuits, and more particularly relates to integrated circuits and methods for fabricating integrated circuits with salicide contacts on non-planar source/drain regions.

### BACKGROUND

Self-aligned silicide (salicide) technology has been widely implemented in existing CMOS technology with polysilicon gates by forming silicide on both the polysilicon gates and source/drain regions in a self-aligned manner, so that the source/drain resistance and polysilicon gate resistance are reduced (from resistance of doped Si), leading to good device performance and yield. The salicide process consists of depositing a layer of transition metal (e.g. Ti, Co, Ni, Al, etc.) on a silicon surface followed by a rapid thermal anneal (RTA). As is well-known, a chemical reaction occurs between silicon and metal to form silicide while metal contacting silicon-oxide, or other materials that do not act as a nucleating layer for silicon during selective epitaxial growth processes, remains non-reacted and does not form silicide. After removing the non-reacted metal by wet etch, the silicide formed on silicon areas is self-aligned with the adjacent gate structure.

In advanced CMOS at 32 nanometer (nm) node and beyond, high-k metal-gate (HKMG) technology is the standard practice and the salicide technology is performed on source/drain regions after gate/spacer formation and epitaxial layer growth on source/drain regions (in gate first flow) or after replacement gate (RMG) formation (in gate-last flow).

Salicide is also used for non-planar integrated circuits, such with FinFET technology and is performed on the source/drain regions after gate/spacer formation (gate-first flow) or after RMG (gate-last flow). However, for non-planar integrated circuits, there is a high risk of electrical shorting at the silicided source/drain regions because the silicide is near the metallurgical junction at the bottom of the source/drain regions.

Accordingly, it is desirable to provide integrated circuits and methods for fabricating integrated circuits with salicide contacts on non-planar source/drain regions. In addition, it is desirable to provide integrated circuits and methods for fabricating integrated circuits which reduce or eliminate electrical shorting at silicided source/drain regions. Furthermore, other desirable features and characteristics will become apparent from the subsequent detailed description and the appended claims, taken in conjunction with the accompanying drawings and the foregoing technical field and background.

### BRIEF SUMMARY

Integrated circuits and methods for fabricating integrated circuits are provided. In accordance with one embodiment, a method for fabricating an integrated circuit includes forming a fin over a semiconductor substrate. The method further includes selectively epitaxially growing a silicon-containing material on the fin and providing the fin with a diamond-shaped cross-section and with an upper portion and a lower portion. The lower portion of the fin is covered with a masking layer. Further, a salicide layer is formed on the upper portion of the fin, and the masking layer prevents formation of the salicide layer on the lower portion of the fin.

In another embodiment, a method for fabricating an integrated circuit includes forming a fin over a semiconductor substrate. The fin has a lower portion adjacent the semiconductor substrate and an upper portion. The method includes covering the lower portion of the fin with a masking layer. Further, the method includes forming a salicide layer on the upper portion of the fin.

In accordance with another embodiment, an integrated circuit includes a semiconductor substrate and a fin formed on the semiconductor substrate. The fin has a source/drain with a lower surface adjacent the semiconductor substrate and an upper surface. The integrated circuit further includes a gate overlying the fin and a metal salicide layer formed on the upper surface of the source/drain. The lower surface of the source/drain separates the metal salicide layer from the semiconductor substrate.

### BRIEF DESCRIPTION OF THE DRAWINGS

Embodiments of methods for fabricating integrated circuits with silicide contacts on non-planar transistors will hereinafter be described in conjunction with the following drawing figures, wherein like numerals denote like elements, and wherein:

FIG. 1 illustrates, in perspective view, a portion of an integrated circuit having a non-planar multi-gate transistor in accordance with an embodiment herein; and

FIGS. 2-9 illustrate, in cross section, a portion of an integrated circuit and method steps for fabricating an integrated circuit in accordance with various embodiments herein.

### DETAILED DESCRIPTION

The following detailed description is merely exemplary in nature and is not intended to limit integrated circuits or the methods for fabricating integrated circuits as claimed herein. Furthermore, there is no intention to be bound by any expressed or implied theory presented in the preceding technical field, background or brief summary, or in the following detailed description.

In accordance with the various embodiments herein, integrated circuits and methods for fabricating integrated circuits with salicide contacts on non-planar source/drain regions are provided. Problems faced by conventional processes when forming silicide contacts to non-planar source/drain regions may be avoided. Specifically, it is contemplated herein that silicide be formed on portions of source/drain regions that are distanced from the underlying semiconductor substrate. More specifically, a portion of the source/drain regions, between the silicide layer and the semiconductor substrate, remains unsilicided and inhibits shorting between the silicide layer and the semiconductor substrate.

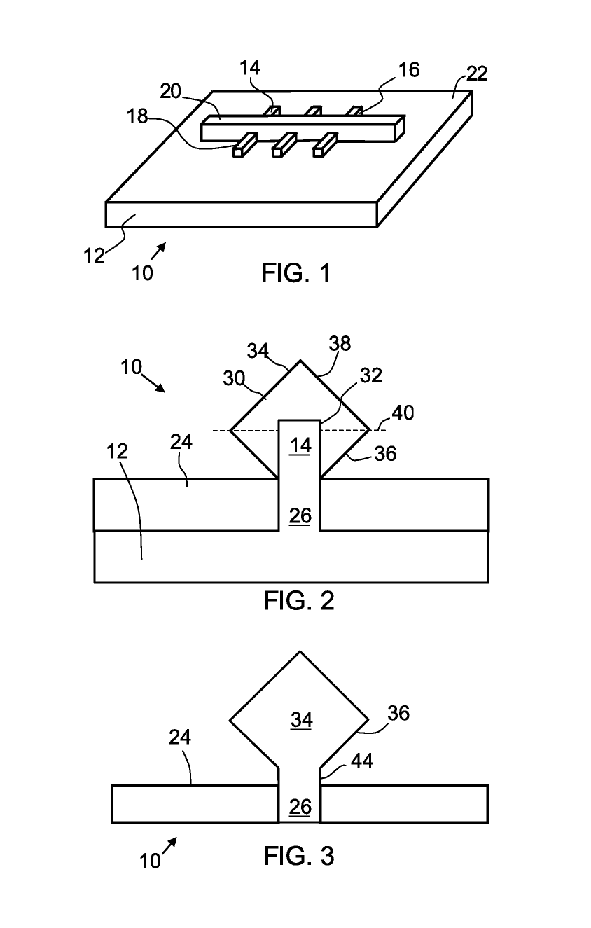

FIGS. 1-9 illustrate steps in accordance with various embodiments of methods for fabricating integrated circuits. Various steps in the design and composition of integrated circuits are well known and so, in the interest of brevity, many conventional steps will only be mentioned briefly herein or will be omitted entirely without providing the well known process details. Further, it is noted that integrated circuits include a varying number of components and that single components shown in the illustrations may be representative of multiple components.

In FIG. 1, in an exemplary embodiment, the method for fabricating an integrated circuit 10 begins by providing a semiconductor substrate 12. Structures 14, such as fins, are formed on the semiconductor substrate 12. Each fin 14 has a source region 16 and a drain region 18 which are defined in relation to gate 20.

The fins 14 are formed according to known processes. For instance, when using a silicon-on-oxide semiconductor substrate 12, portions of the top silicon layer are etched or otherwise removed leaving the fin structures 14 formed from silicon remaining on the underlying oxide layer 22. As shown, gate 20 is formed across the fin structures 14. Gate oxide and/or nitride capping layers (not shown) may be deposited over the fin structures 14 before the gate 20 is formed. The gate 20 is formed by typical lithographic processing.

FIGS. 2-9 are cross-sectional views of a source or drain region 16 or 18 in a single fin structure 14 of FIG. 1 during various steps of processing. In FIG. 2, the fin structure 14 has been formed and an isolation layer 24, such as oxide, has been formed over the semiconductor substrate 12. Further, patterning, implanting, and annealing processes have formed a well 26 in the semiconductor substrate 12 below the fin 14. A selective epitaxial growth process is used to form an additional silicon layer 30 on exposed silicon surfaces 32, i.e., over the fin structure 14, for form an enhanced fin structure 34. As shown, the additional silicon layer 30 provides the fin structure 34 with a “diamond-shaped” cross-section. This shape occurs due to the slower rate of growth on the (111) surface.

As shown in FIG. 2, the fin structure 34 has lower surfaces 36 adjacent the semiconductor substrate 12. The fin structure 34 has upper surfaces 38 positioned beyond the lower surfaces 36 with respect to the semiconductor substrate 12, with a mid-line 40 defined between the lower surfaces 36 and upper surfaces 38. In FIG. 3, the isolation layer 24 is recessed to expose a vertical portion 44 of the fin structure 34 below the lower surfaces 36. It is noted that FIGS. 3-9 do not illustrate the semiconductor substrate 12 though it is understood to remain positioned beneath the isolation layer 24.

In FIG. 4, a masking layer 50 is formed over the isolation layer 24 and the fin structure 34. In an exemplary embodiment, the masking layer 50 is an insulating layer, such as silicon oxide or silicon nitride, and is conformally deposited, such as by atomic layer deposition (ALD) or chemical vapor deposition (CVD). The masking layer 50 may have a thickness of about two to about ten nanometers in an exemplary embodiment. As shown in FIG. 4, the fin structure 34 is encapsulated by the masking layer 50.

In FIG. 5, an etch process has been performed to remove the masking layer 50 formed on the upper surfaces 38 of the fin structure 34. In an exemplary method, an anisotropic dry etch is performed and removes the masking layer 50 from the upper surfaces 38, as well as from a non-covered portion 52 of the isolation layer 24. The etch process also serves to pre-clean the upper surfaces 38.

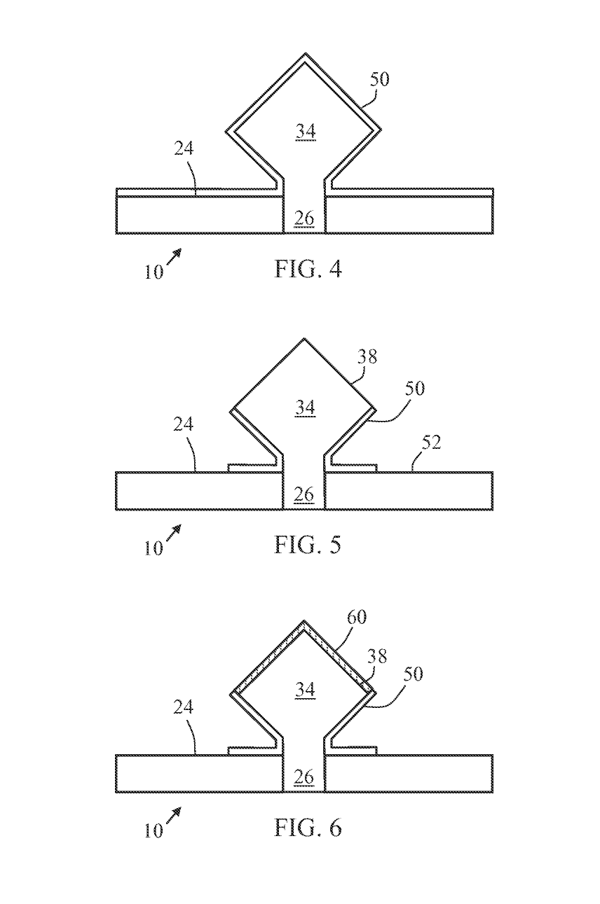

In FIG. 6, a self-aligned silicidation process has been performed to form a salicide layer 60 on the upper surfaces 38 of the fin structure 34. Specifically, in the process a silicide metal is deposited over the isolation layer 24, masking layer 50, and upper surfaces 38 of the fin structure 34, and then annealed. During the anneal, the silicide metal reacts with the silicon in the fin structure 34 to form the salicide layer 60 on the upper surfaces 38 of the fin structure 34. The silicide metal does not react with the isolation layer 24 or masking layer 50. Then, the unreacted silicide metal is removed.

In an alternate embodiment, the masking layer 50 deposited in FIG. 4 is a conductive layer, such as metal oxide or metal nitride, that is conformally deposited, such as by ALD, chemical vapor deposition (CVD), or physical vapor deposition (PVD) (sputter) processes. Again, the thickness of the masking layer 50 is about two to about ten nanometers in an exemplary embodiment. For a metal oxide or metal nitride masking layer 50, the etch process performed in FIG. 5 is an anisotropic dry etch which removes the masking layer 50 from, and pre-cleans, the upper surfaces 38 of the fin structure 34. The silicidation process described in relation to FIG. 6 is then performed to form the salicide layer 60 over the upper surfaces 38 of the fin structure 34.

Referring now to FIGS. 7-9, another embodiment for forming the salicide layer 60 selectively on the upper surfaces 38 of the fin structure 34 is shown. In FIG. 7, the masking layer 50 is conformally formed over the isolation layer 24 and the lower surfaces 36 of the fin structure 34. For example, the masking layer 50 may be spin-on-glass which is spin-coated to a thickness of about ten to about thirty nanometers. The thickness should be sufficient to allow the masking layer 50 to cover at least about half of the fin structure 34. If the upper surfaces 38 include any spin-on-glass, an etch may be performed to remove the spin-on-glass from the upper surfaces 38. For example, a wet or dry etch may be performed. The etch also precleans the upper surfaces 38.

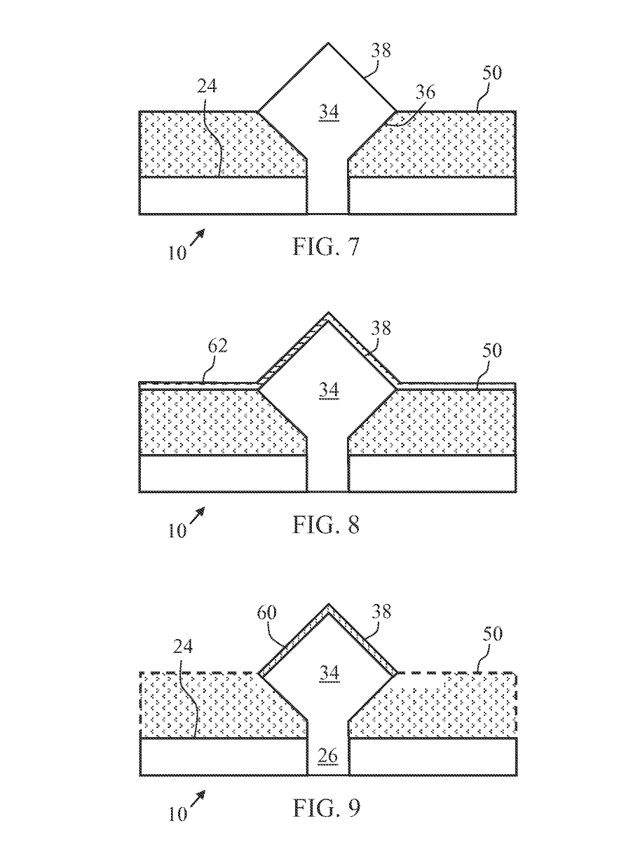

In FIG. 8, silicide metal 62 is deposited over the masking layer 50 and the upper surfaces 38 of the fin structure 34. Then, the integrated circuit 10 is annealed to react the silicide metal 62 with the silicon fin structure 34. The silicide metal 62 does not react with the masking layer 50. The unreacted silicide metal 62 is then removed leaving the salicide layer 60 formed at the upper surfaces 38 of the fin structure 34 as shown in FIG. 9. In FIG. 9, the masking layer 50 is shown remaining on the isolation layer 24, though it can be removed by wet or dry clean processes.

Each of the embodiments disclosed herein forms the salicide layer 60 at a location non-adjacent the well 26 in the semiconductor substrate 12. Specifically, the salicide layer 60 is distanced from the well 26 by at least the length of the lower surfaces 36. While the embodiments discussed above illustrate the salicide layer 60 being formed only on the upper surfaces 38, it is contemplated that the salicide layer 60 be formed on an upper portion of the lower surfaces 36 as well, provided that a gap remains between the salicide layer 60 and the well 26 or semiconductor substrate 12 to eliminate shorting between the salicide layer 60 and the semiconductor substrate 12. Further, the processes illustrated and described above can be applied for n-type or p-type source/drain regions 16, 18.

The integrated circuits and fabrication methods described herein result in reduced shorting at the silicide layers on source/drain regions in non-planar structures, such as fins in FinFETs. Further, the fabrication methods described herein are easily incorporated into existing fabrication processes.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

1. A method for fabricating an integrated circuit comprising:
forming a fin over a semiconductor substrate;
selectively epitaxially growing a silicon-containing material on the fin and forming a diamond-shaped fin structure with a diamond-shaped cross-section formed by upper surfaces and lower surfaces;
covering the lower surfaces of the diamond-shaped fin structure with a masking layer; and
forming a salicide layer on the upper surfaces of the diamond-shaped fin structure, wherein the masking layer prevents formation of the salicide layer on the lower surfaces of the diamond-shaped fin structure.

2. The method of claim 1 wherein covering the lower surfaces of the diamond-shaped fin structure with a masking layer comprises:
conformally depositing the masking layer over the upper surfaces and lower surfaces of the diamond-shaped fin structure; and
etching the masking layer from the upper surfaces of the diamond-shaped fin structure.

3. The method of claim 1 wherein selectively epitaxially growing a silicon-containing material on the fin and forming a diamond-shaped fin structure with a diamond-shaped cross-section formed by upper surfaces and lower surfaces comprises defining vertical surfaces of the fin below the lower surfaces of the diamond-shaped fin structure; and wherein covering the lower surfaces of the diamond-shaped fin structure with a masking layer comprises covering the vertical surfaces of the fin with the masking layer.

4. The method of claim 2 wherein conformally depositing the masking layer over the upper surfaces and lower surfaces of the diamond-shaped fin structure comprises depositing silicon oxide over the upper surfaces and lower surfaces of the fin by atomic layer deposition (ALD) or chemical vapor deposition (CVD).

5. The method of claim 4 wherein etching the masking layer from the upper surfaces of the diamond-shaped fin structure comprises performing an anisotropic dry etch to remove the masking layer from the upper surfaces of the diamond-shaped fin structure.

6. The method of claim 2 wherein conformally depositing the masking layer over the upper surfaces and lower surfaces of the diamond-shaped fin structure comprises depositing metal oxide over the upper surfaces and lower surfaces of the diamond-shaped fin structure by atomic layer deposition (ALD), chemical vapor deposition (CVD), or physical vapor deposition (PVD).

7. The method of claim 6 wherein etching the masking layer from the upper surfaces of the diamond-shaped fin structure comprises performing an anisotropic dry etch to remove the masking layer from the upper surfaces of the diamond-shaped fin structure.

8. The method of claim 7 further comprising leaving the metal oxide masking layer on the semiconductor substrate to reduce source/drain resistance after etching the masking layer from the upper surfaces of the diamond-shaped fin structure.

9. The method of claim 1 wherein covering the lower surfaces of the diamond-shaped fin structure with a masking layer comprises spin-coating the lower surfaces of the diamond-shaped fin structure with spin-on-glass.

10. The method of claim 9 further comprising:
forming an isolation layer overlying the semiconductor substrate and adjacent the fin; wherein covering the lower surfaces of the diamond-shaped fin structure with a masking layer comprises covering the isolation layer with the masking layer; and
performing an anisotropic etch to remove the masking layer from the upper surfaces of the diamond-shaped fin structure and from an exposed portion of the isolation layer, wherein the upper surfaces of the diamond-shaped fin structures mask a non-exposed portion of the isolation layer.

11. The method of claim 1 further comprising:
forming an isolation layer overlying the semiconductor substrate and adjacent the fin; wherein covering the lower surfaces of the diamond-shaped fin structure with a masking layer comprises covering the isolation layer with the masking layer; and
etching the masking layer from the upper surfaces of the diamond-shaped fin structure and from a portion of the isolation layer.

12. A method for fabricating an integrated circuit comprising:
forming a fin over a semiconductor substrate, wherein the fin has a lower portion adjacent the semiconductor substrate and an upper portion;
forming an isolation layer over the semiconductor substrate and adjacent the fin;
covering the fin and the isolation layer with a masking layer;
etching the masking layer from the upper portion of the fin and from a portion of the isolation layer; and
forming a salicide layer on the upper portion of the fin.

13. The method of claim 12 further comprising selectively epitaxially growing a silicon-containing material on the fin and providing the fin with a diamond-shaped cross-section formed by the upper portion and the lower portion.

14. The method of claim 12 wherein covering the fin with a masking layer comprises conformally depositing the masking layer over the upper portion and lower portion of the fin; and wherein etching the masking layer from the upper portion of the fin and from a portion of the isolation layer comprises anisotropically etching exposed portions of the masking layer overlying the upper portion of the fin and the portion of the isolation layer wherein the upper portion of the fin masks a non-exposed portion of the masking layer overlying the isolation layer.

15. The method of claim 14 wherein conformally depositing the masking layer over the upper portion and lower portion of the fin comprises conformally depositing the masking layer with a thickness of about 2 nanometers (nm) to about 10 nm.

16. The method of claim 14 wherein conformally depositing the masking layer over the upper portion and lower portion of the fin comprises depositing silicon oxide, or metal oxide, over the upper portion and lower portion of the fin by atomic layer deposition (ALD) chemical vapor deposition (CVD), or physical vapor deposition (PVD).

17. The method of claim 16 wherein etching the masking layer from the upper portion of the fin and from a portion of the isolation layer comprises performing an anisotropic dry etch to remove the masking layer from the upper portion of the fin and from the portion of the isolation layer.

18. The method of claim 12 wherein covering the lower portion of the fin with a masking layer comprises spin-coating the lower portion of the fin with spin-on-glass.

19. The method of claim 18 wherein covering the lower portion of the fin with a masking layer further comprises removing any spin-on-glass from the upper portion of the fin by a wet or dry etch process.

20. (canceled)
